(19) United States
(12) Patent Application Publication
(10) Pub. No.: US 2026/0107486 A1
(43) Pub. Date: Apr. 16, 2026

(54) BIPOLAR JUNCTION TRANSISTOR

(71) Applicant: UNITED MICROELECTRONICS CORP., Hsin-Chu City (TW)

(72) Inventor: Sheng Cho, Hsinchu County (TW)

(73) Assignee: UNITED MICROELECTRONICS CORP., Hsin-Chu City (TW)

(21) Appl. No.: 18/946,814

(22) Filed: Nov. 13, 2024

(30) Foreign Application Priority Data
Oct. 15, 2024 (TW) 113139064

(51) Int. Cl. H01L 29/735; H01L 29/06; H01L 29/08; H01L 29/10

(52) U.S. Cl. CPC H10D 10/60; H10D 62/115; H10D 62/134; H10D 62/137; H10D 62/184

(57) ABSTRACT

A bipolar junction transistor includes an emitter region, a base region, a collector region and an isolation structure. The base region is disposed adjacent to a first side of the emitter region. The collector region is disposed adjacent to a second side of the emitter region. The isolation structure is disposed between the emitter region and each of the base region and the collector region.

### BACKGROUND OF THE INVENTION

### 1. Field of the Invention

The present disclosure relates to the field of semiconductor devices, and more particularly, to a bipolar junction transistor (BJT).

### 2. Description of the Prior Art

A BJT is mainly composed of three portions of a semiconductor material with different doping degrees, and the charge flow in the BJT is mainly based on the diffusion and the drift of carriers at the PN junction. Taking an NPN transistor as an example, electrons in the emitter region with a higher doping degree move to the base region through diffusion according to the design. In the base region, electron holes are majority carriers and electrons are minority carriers. Since the base region is very thin, these electrons reach the collector region through drift, which forms the collector current. Therefore, the BJT is classified as a minority carrier device. The BJT is capable of amplifying signals, and have excellent capabilities for power controlling, high-speed operation and durability. Therefore, the BJT is frequently used to form amplifier circuits or to drive apparatus, such as speakers and motors. Moreover, the BJT is widely applied in the products of aerospace engineering, medical equipment and robots. Therefore, how to improve the structure of the BJT is the goal of the relevant industries.

### SUMMARY OF THE INVENTION

According to one embodiment of the present disclosure, a bipolar junction transistor includes an emitter region, a base region, a collector region and an isolation structure. The base region is disposed adjacent to a first side of the emitter region. The collector region is disposed adjacent to a second side of the emitter region. The isolation structure is disposed between the emitter region and each of the base region and the collector region.

According to another embodiment of the present disclosure, a bipolar junction transistor includes an emitter region, an isolation structure, a base region and a collector region. The isolation structure surrounds the emitter region. The base region is disposed adjacent to a first side and a second side of the emitter region. The collector region is disposed adjacent to a third side and a fourth side of the emitter region.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic top view showing a bipolar junction transistor according to an embodiment of the present disclosure.

FIG. 2 is a schematic cross-sectional view of the bipolar junction transistor taken along line A-A′ shown in FIG. 1.

FIG. 3 is a schematic cross-sectional view of the bipolar junction transistor taken along line B-B′ shown in FIG. 1.

FIG. 4 is a schematic top view showing a bipolar junction transistor according to another embodiment of the present disclosure.

FIG. 5 is a schematic cross-sectional view of the bipolar junction transistor taken along line C-C′ shown in FIG. 4.

FIG. 6 is a schematic cross-sectional view of the bipolar junction transistor taken along line D-D′ shown in FIG. 4.

FIG. 7 is a schematic top view showing a bipolar junction transistor according to yet another embodiment of the present disclosure.

FIG. 8 is a schematic cross-sectional view of the bipolar junction transistor taken along line E-E′ shown in FIG. 7.

FIG. 9 is a schematic cross-sectional view of the bipolar junction transistor taken along line F-F′ shown in FIG. 7.

### DETAILED DESCRIPTION

In the following detailed description of the embodiments, reference is made to the accompanying drawings which form a part thereof, and in which is shown by way of illustration specific embodiments in which the disclosure may be practiced. In this regard, directional terminology, such as up, down, left, right, front, back, bottom or top is used with reference to the orientation of the Figure(s) being described. The elements of the present disclosure can be positioned in a number of different orientations. As such, the directional terminology is used for purposes of illustration and is in no way limiting. In addition, identical numeral references or similar numeral references are used for identical elements or similar elements in the following embodiments.

Hereinafter, for the description of “the first feature is formed on or above the second feature”, it may refer that “the first feature is in contact with the second feature directly”, or it may refer that “there is another feature between the first feature and the second feature”, such that the first feature is not in contact with the second feature directly.

It is understood that, although the terms first, second, etc. may be used herein to describe various elements, regions, layers and/or sections, these elements, regions, layers and/or sections should not be limited by these terms. These terms may be only used to distinguish one element, region, layer and/or section from another element, region, layer and/or section. Terms such as “first,” “second,” and other numerical terms when used herein do not imply a sequence or order unless clearly indicated by the context. Thus, a first element, region, layer and/or section discussed below could be termed a second element, region, layer and/or section without departing from the teachings of the embodiments. The terms used in the claims may not be identical with the terms used in the specification, but may be used according to the order of the elements claimed in the claims.

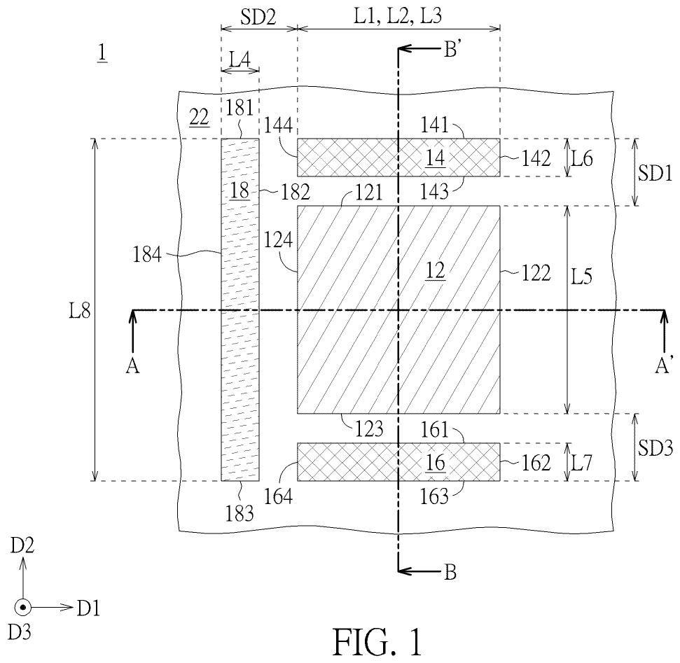

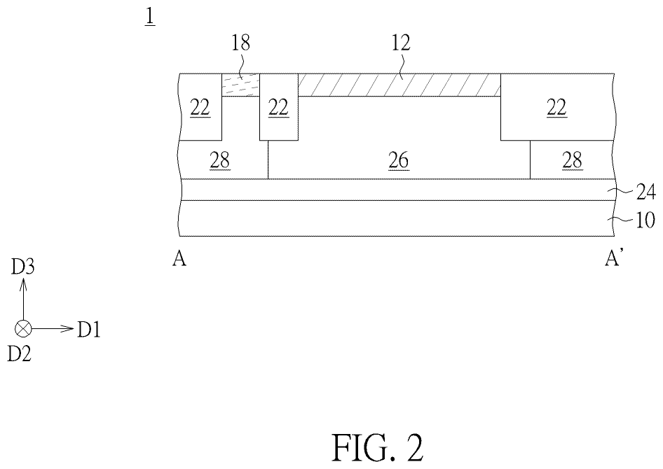

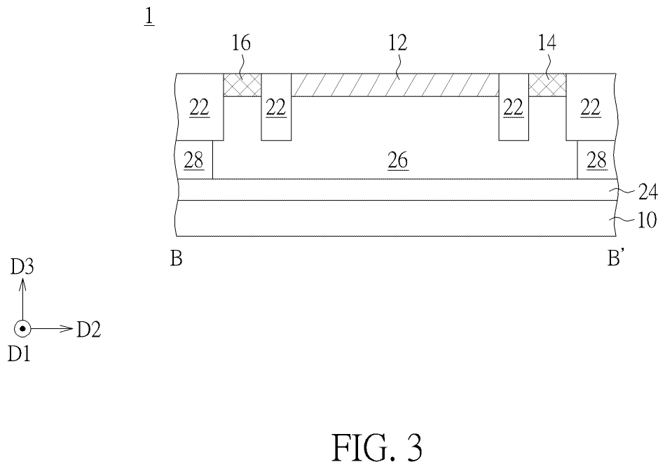

Please refer to FIG. 1 to FIG. 3. FIG. 1 is a schematic top view showing a bipolar junction transistor 1 according to an embodiment of the present disclosure. FIG. 2 is a schematic cross-sectional view of the bipolar junction transistor 1 taken along line A-A′ shown in FIG. 1. FIG. 3 is a schematic cross-sectional view of the bipolar junction transistor 1 taken along line B-B′ shown in FIG. 1. The bipolar junction transistor 1 includes an emitter region 12, two base regions 14 and 16, a collector region 18 and an isolation structure 22 disposed in a substrate 10. The substrate 10 may be a doped silicon substrate, a dope epitaxial silicon substrate, a doped silicon carbide substrate or a doped silicon on insulator (SOI) substrate.

The base region 14 is disposed adjacent to a side 121 of the emitter region 12. The base region 16 is disposed adjacent to a side 123 of the emitter region 12. The collector region 18 is disposed adjacent to a side 124 of the emitter region 12. The isolation structure 22 is disposed between the emitter region 12 and the base region 14, between the emitter region 12 and the base region 16, and between the emitter region 12 and the collector region 18. For example, the isolation structure 22 may be a shallow trench isolation. The isolation structure 22 is for defining and separating the emitter region 12, the base regions 14 and 16, and the collector region 18, and providing the electrical isolation function between the emitter region 12, the base regions 14 and 16, and the collector region 18. Herein, the isolation structure 22 surrounds the emitter region 12, the isolation structure 22 surrounds the base region 14, the isolation structure 22 surrounds the base region 16, and the isolation structure 22 surrounds the collector region 18. In the present disclosure, one region (for example, one of the emitter region 12, the base regions 14 and 16, and the collector region 18) is disposed adjacent to another region (for example, another one of the emitter region 12, the base regions 14 and 16, and the collector region 18) may refer that only the isolation structure 22 is disposed between the region and the another region and no other regions are disposed between the region and the another region. With the arrangement of the emitter region 12, the base regions 14 and 16, and the collector region 18, it is beneficial to reduce the area of the bipolar junction transistor 1 and improve the electrical performance of the bipolar junction transistor 1. For example, the direct current gain of the bipolar junction transistor 1 can be increased.

Specifically, as shown in FIG. 1, the base regions 14 and 16 and the collector region 18 are disposed adjacent to different sides of the emitter region 12. The base region 14 is only disposed adjacent to a side (i.e., the side 121) of the emitter region 12, but not disposed adjacent to other sides 122, 123 and 124 of the emitter region 12. The base region 16 is only disposed adjacent to a side (i.e., the side 123) of the emitter region 12, but not disposed adjacent to other sides 121, 122 and 124 of the emitter region 12. The collector region 18 is only disposed adjacent to a side (i.e., the side 124) of the emitter region 12, but not disposed adjacent to other sides 121, 122 and 123 of the emitter region 12.

In this embodiment, the number of the base regions 14 and 16 is two. The base region 14 extends along the horizontal direction D1 and is disposed adjacent to the side 121 of the emitter region 12. The other base region 16 extends along the horizontal direction D1 and disposed adjacent to the side 123 of the emitter region 12, and the side 123 is opposite to the side 121. In addition, the base regions 14 and 16 are arranged symmetrically with respect to a center (not labeled) of the emitter region 12, and a cross section of the bipolar junction transistor 1 taken along the horizontal direction D2 is symmetric, as shown in FIG. 3. However, the present disclosure is not limited thereto. In other embodiments, the bipolar junction transistor 1 may only include a single base region, i.e., the base region 14 or the base region 16. In this embodiment, the number of the collector region 18 is one. Therefore, a cross section of the bipolar junction transistor 1 taken along the horizontal direction D1 is asymmetric, as shown in FIG. 2.

In FIG. 1, the base regions 14 and 16 and the collector region 18 are respectively disposed adjacent to different sides of the emitter region 12, and the base regions 14 and 16 and the collector region 18 are not disposed adjacent to a same side of the emitter region 12. In addition, the base region 14 is not disposed between the emitter region 12 and the collector region 18, and the base region 16 is not disposed between the emitter region 12 and the collector region 18. That is, there is only the isolation structure 22 disposed between the emitter region 12 and the collector region 18, and the base regions 14 and 16 are not disposed between the emitter region 12 and the collector region 18.

In a top view of the bipolar junction transistor 1, the emitter region 12 may be formed in a square shape, and each of the base regions 14 and 16 and the collector region 18 may be formed in a strip shape or a rectangular shape. The base regions 14 and 16 extend along the horizontal direction D1, and the collector region 18 extends along the horizontal direction D2. The horizontal direction D1 is perpendicular to the horizontal direction D2. In the horizontal direction D2, the base regions 14 and 16 overlap the emitter region 12, the collector region 18 does not overlap the emitter region 12, and the collector region 18 does not overlap the base regions 14 and 16. In the present disclosure, in a schematic top view/top view of the bipolar junction transistor 1 or an element thereof may refer to view the bipolar junction transistor 1 in a direction opposite to the vertical direction D3. In the present disclosure, when an element extends along a direction, it may refer that the element has a maximum length in the direction.

The base region 14 may include two short sides (i.e., the sides 142 and 144) opposite to each other and two long sides (i.e., the sides 141 and 143) opposite to each other. The base region 16 may include two short sides (i.e., the sides 162 and 164) opposite to each other and two long sides (i.e., the sides 161 and 163) opposite to each other. The collector region 18 may include two short sides (i.e., the sides 181 and 183) opposite to each other and two long sides (i.e., the sides 182 and 184) opposite to each other.

A short side (i.e., the side 181) of the collector region 18 is aligned with a long side (i.e., the side 141) of the base region 14, and the other short side (i.e., the side 183) of the collector region 18 is aligned with a long side (i.e., the side 163) of the other base region 16. Two opposite sides (i.e., the sides 181 and 183) of the collector region 18 in the horizontal direction D2 are respectively aligned with an outer side (i.e., the side 141) of the base region 14 and an outer side (i.e., the side 163) of the other base region 16. Herein, a length L8 of the collector region 18 in the horizontal direction D2 is greater than a length L5 of the emitter region 12 in the horizontal direction D2, and the length L8 of the collector region 18 in the horizontal direction D2 is greater than a length L6 of the base region 14 in the horizontal direction D2. The length L8 of the collector region 18 in the horizontal direction D2 is greater than a length L7 of the base region 16 in the horizontal direction D2, and the length L8 of the collector region 18 in the horizontal direction D2 is greater than the sum of the lengths (i.e., L5+L6+L7) of the emitter region 12 and the two collector regions 14 and 16 in the horizontal direction D2.

The two sides (i.e., the sides 142 and 144) of the base region 14 opposite to each other in the horizontal direction D1 are respectively aligned with two sides (i.e., the sides 122 and 124) of the emitter region 12 opposite to each other in the horizontal direction D1, and respectively aligned with two sides (i.e., the sides 162 and 164) of the base region 16 opposite to each other in the horizontal direction D1. In other words, a length L2 of the base region 14 in the horizontal direction D1 and a length L1 of the emitter region 12 in the horizontal direction D1 are the same, and a length L3 of the base region 16 in the horizontal direction D1 and the length L1 of the emitter region 12 in the horizontal direction D1 are the same. In addition, a length L4 of the collector region 18 in the horizontal direction D1 and the length L1 of the emitter region 12 in the horizontal direction D1 are different. Herein, the length L4 is smaller than the length L1.

According to an embodiment of the present disclosure, a width of the base region 14 (i.e., the length L6 of the base region 14 in the horizontal direction D2), a width of the base region 16 (i.e., the length L7 of the base region 16 in the horizontal direction D2) and a width of the collector region 18 (i.e., the length L4 of the collector region 18 in the horizontal direction D1) are all the same.

In FIG. 1, in the horizontal direction D2, there is a shortest distance SD1 between the outer side (i.e., the side 141) of the base region 14 and the emitter region 12. In the horizontal direction D1, there is a shortest distance SD2 between the outer side (i.e., the side 184) of the collector region 18 and the emitter region 12. The shortest distance SD1 is smaller than the shortest distance SD2. Similarly, in the horizontal direction D2, there is a shortest distance SD3 between the outer side (i.e., the side 163) of the base region 16 and the emitter region 12. In the horizontal direction D1, there is the shortest distance SD2 between the outer side (i.e., the side 184) of the collector region 18 and the emitter region 12. The shortest distance SD3 is smaller than the shortest distance SD2. According to an embodiment of the present disclosure, the ratio of the shortest distance SD1 to the shortest distance SD2 may be 0.7 to 0.8, and the ratio of the shortest distance SD3 to the shortest distance SD2 may be 0.7 to 0.8.

As shown in FIG. 1, in a top view of the bipolar junction transistor 1, the layout of the emitter region 12, the base regions 14 and 16 and the collector region 18 includes an E shape.

As shown in FIG. 2 and FIG. 3, in this embodiment, the bipolar junction transistor 1 is an NPN transistor, the emitter region 12 includes an N+ region, each of the base regions 14 and 16 includes a P+ region, and the collector region 18 includes an N+ region. A P well 26 is disposed in the substrate 10 directly below the emitter region 12 and the base regions 14 and 16, an N well 28 is disposed in the substrate 10 directly below the collector region 18, and a deep N well 24 is disposed in the substrate 10 below the P well 26 and the N well 28. Furthermore, the emitter region 12 is a region with a high doping concentration. The emitter region 12 is mainly configured to inject free electrons into the base regions 14 and 16 through the P well 26. Therefore, although both the emitter region 12 and the collector region 18 of this embodiment are N+ regions, the doping concentration of the N+ region of the emitter region 12 is preferably greater than the doping concentration of the N+ region of the collector region 18. The operating principle of the bipolar junction transistor 1 is well known to those skilled in the art and is omitted herein.

Herein, the bipolar junction transistor 1 is an NPN transistor, which is exemplary, and the present disclosure is not limited thereto. In other embodiments, the conductivity types of the emitter region 12, the base regions 14 and 16, the collector region 18, the P well 26, the N well 28 and the deep N well 24 may be all reversed, so that the bipolar junction transistor 1 is a PNP transistor.

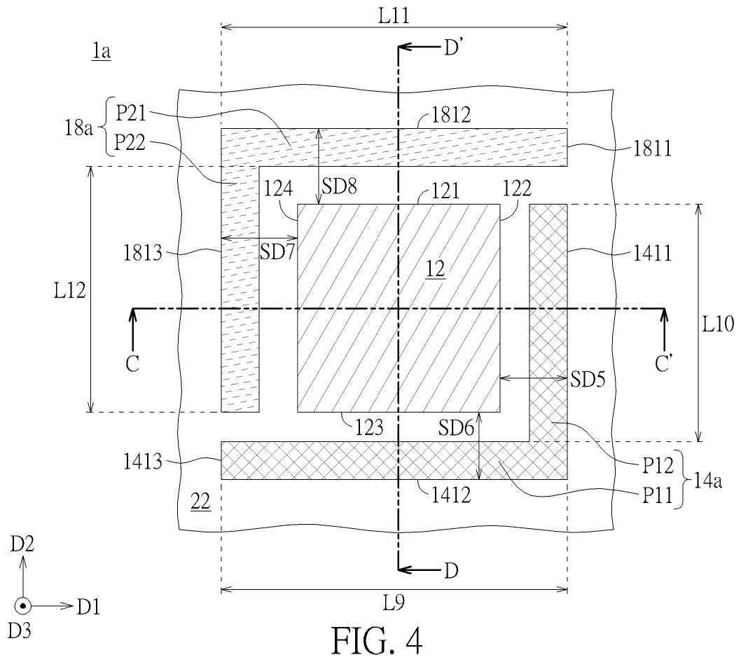

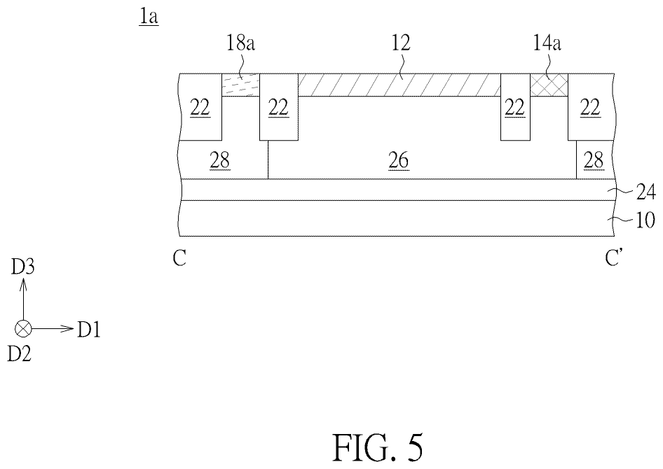

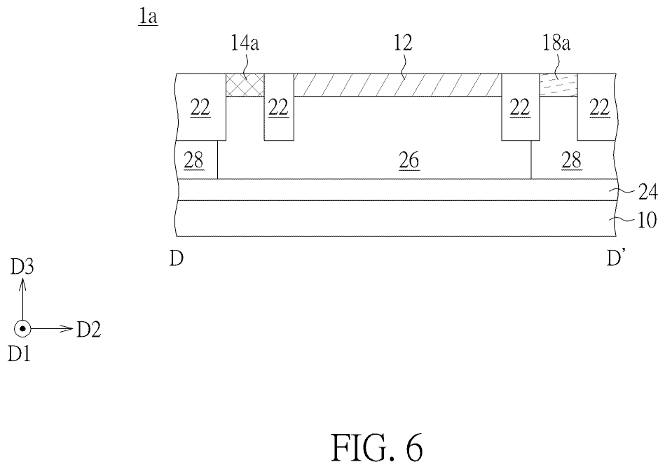

Please refer to FIG. 4 to FIG. 6. FIG. 4 is a schematic top view showing a bipolar junction transistor 1a according to another embodiment of the present disclosure. FIG. 5 is a schematic cross-sectional view of the bipolar junction transistor 1a taken along line C-C′ shown in FIG. 4. FIG. 6 is a schematic cross-sectional view of the bipolar junction transistor 1a taken along line D-D′ shown in FIG. 4. The bipolar junction transistor 1a includes an emitter region 12, a base region 14a, a collector region 18a and an isolation structure 22 disposed in the substrate 10. The isolation structure 22 surrounds the emitter region 12, the base region 14a is disposed adjacent to a side 122 and a side 123 of the emitter region 12, and the collector region 18a is disposed adjacent to a side 121 and a side 124 of the emitter region 12. Specifically, the isolation structure 22 is disposed between the emitter region 12 and the base region 14a and between the emitter region 12 and the collector region 18a. Furthermore, the isolation structure 22 surrounds the base region 14a, and the isolation structure 22 surrounds the collector region 18a. With the arrangement of the emitter region 12, the base region 14a and the collector region 18a, it is beneficial to reduce the area of the bipolar junction transistor 1a and improve the electrical performance of the bipolar junction transistor 1a. For example, the direct current gain of the bipolar junction transistor 1a can be increased.

As shown in FIG. 4, the base region 14a and the collector region 18a are disposed adjacent to different sides of the emitter region 12. In a top view of the bipolar junction transistor 1a, the emitter region 12 may be formed in a square shape, the base region 14a may be formed in an L shape, and the collector region 18a may be formed in an L shape. Specifically, the base region 14a includes a first portion P11 extending along the horizontal direction D1 and disposed adjacent to the side 123 of the emitter region 12 and a second portion P12 extending along the horizontal direction D2 and disposed adjacent to the side 122 of the emitter region 12. A length L9 of the first portion P11 in the horizontal direction D1 is different from a length L10 of the second portion P12 in the horizontal direction D2. Herein, the length L9 is greater than the length L10. Similarly, the collector region 18a includes a first portion P21 extending along the horizontal direction D1 and disposed adjacent to the side 121 of the emitter region 12 and a second portion P22 extending along the horizontal direction D2 and disposed adjacent to the side 124 of the emitter region 12. A length L11 of the first portion P21 in the horizontal direction D1 is different from a length L12 of the second portion P22 in the horizontal direction D2. Herein, the length L11 is greater than the length L12.

As shown in FIG. 4, the base region 14a and the collector region 18a are disposed adjacent to different sides of the emitter region 12, and the base region 14a is only disposed adjacent to two sides (i.e., the side 122 and the side 123) of the emitter region 12, but not disposed adjacent to other sides 121 and 124 of the emitter region 12. The collector region 18a is only disposed adjacent to two sides (i.e., the sides 121 and 124) of the emitter region 12, but not disposed adjacent to the sides 122 and 123 of the emitter region 12. In addition, the base region 14a and the collector region 18a are not disposed adjacent to the same side of the emitter region 12. The base region 14a is not disposed between the emitter region 12 and the collector region 18a. That is, the emitter region 12 and the collector region 18a only include the isolation structure 22 disposed therebetween, and do not include the base region 14a disposed therebetween.

In this embodiment, since the collector region 18a and the base region 14a are respectively disposed at the left and right sides of the emitter region 12, the cross section of the bipolar junction transistor 1a taken along the horizontal direction D1 is asymmetrical, as shown in FIG. 5. Since the collector region 18a and the base region 14a are respectively disposed above and below the emitter region 12, the cross section of the bipolar junction transistor 1a taken along the horizontal direction D2 is asymmetric, as shown in FIG. 6.

Two outer sides (i.e., the sides 1811 and 1813) of the collector region 18a opposite to each other in the horizontal direction D1 are respectively aligned with two outer sides (i.e., the sides 1411 and 1413) of the base region 14a opposite to each other in the horizontal direction D1.

In the horizontal direction D1, there is a shortest distance SD5 between the outer side (i.e., the side 1411) of the base region 14a and the emitter region 12. In the horizontal direction D2, there is a shortest distance SD6 between the outer side (i.e., the side 1412) of the base region 14a and the emitter region 12. The shortest distance SD5 may be equal to the shortest distance SD6. In the horizontal direction D1, there is a shortest distance SD7 between the outer side (i.e., the side 1813) of the collector region 18a and the emitter region 12. In the horizontal direction D2, there is a shortest distance SD8 between the outer side (i.e., the side 1812) of the collector region 18a and the emitter region 12. The shortest distance SD7 may be equal to the shortest distance SD8.

In the horizontal direction D1, the shortest distance SD5 between the outer side (i.e., the side 1411) of the base region 14a and the emitter region 12 is smaller than the shortest distance SD7 between the outer side (i.e., the side 1813) of the collector region 18a and the emitter region 12. In the horizontal direction D2, the shortest distance SD6 between the outer side (i.e., the side 1412) of the base region 14a and the emitter region 12 is smaller than the shortest distance SD8 between the outer side (i.e., the side 1812) of the collector region 18a and the emitter region 12. Therefore, in a top view of the bipolar junction transistor 1a, the base region 14a and the collector region 18a are arranged asymmetrically with respect to a center (not labeled) of the emitter region 12. According to an embodiment of the present disclosure, the ratio of the shortest distance SD5 to the shortest distance SD7 may be 0.7 to 0.8, and the ratio of the shortest distance SD6 to the shortest distance SD8 may be 0.7 to 0.8.

According to an embodiment of the present disclosure, a width of the base region 14a (i.e., the length of the first portion P11 in the horizontal direction D2 or the length of the second portion P12 in the horizontal direction D1) and a width of the collector region 18a (i.e., the length of the first portion P21 in the horizontal direction D2 or the length of the second portion P22 in the horizontal direction D1) are the same.

As shown in FIG. 5 and FIG. 6, in this embodiment, the bipolar junction transistor 1a is an NPN transistor, the emitter region 12 includes an N+ region, the base region 14a includes a P+ region, and the collector region 18a includes an N+ region. A P well 26 is disposed in the substrate 10 directly below the emitter region 12 and the base region 14a, an N well 28 is disposed in the substrate 10 directly below the collector region 18a, and a deep N well 24 is disposed in the substrate 10 below the P well 26 and the N well 28. However, the present disclosure is not limited thereto. In other embodiments, the conductivity types of the emitter region 12, the base region 14a, the collector region 18a, the P well 26, the N well 28 and the deep N well 24 can all be reversed, so that the bipolar junction transistor 1a is a PNP transistor. For other details about the bipolar junction transistor 1a, references may be made to the relevant description of the bipolar junction transistor 1 and are omitted herein.

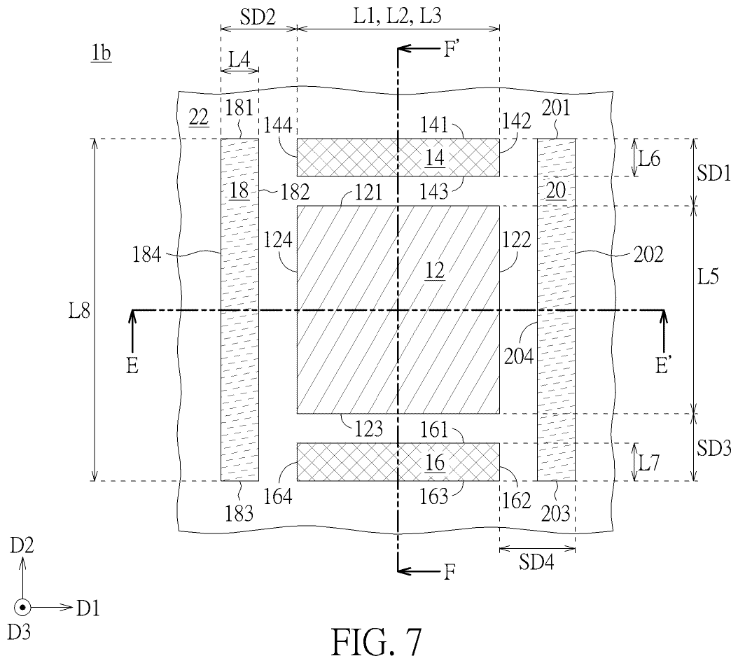

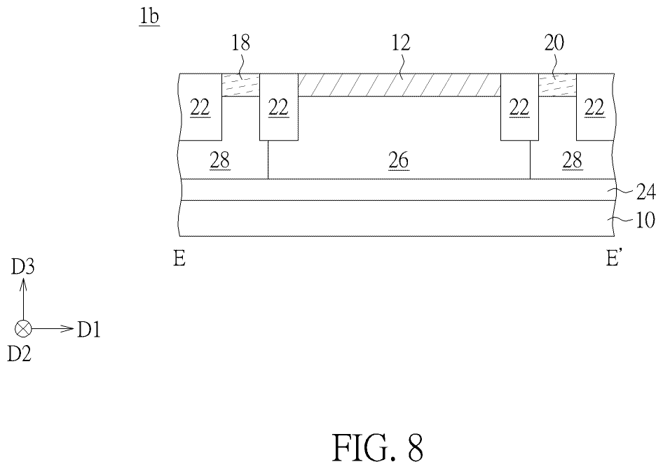

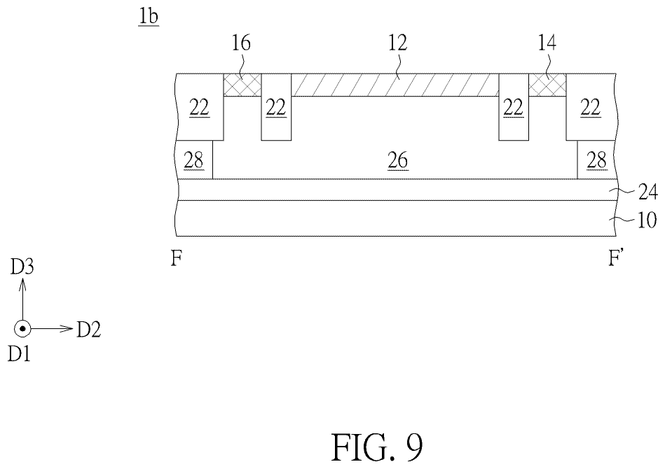

Please refer to FIG. 7 to FIG. 9. FIG. 7 is a schematic top view showing a bipolar junction transistor 1b according to yet another embodiment of the present disclosure. FIG. 8 is a schematic cross-sectional view of the bipolar junction transistor 1b taken along line E-E′ shown in FIG. 7. FIG. 9 is a schematic cross-sectional view of the bipolar junction transistor 1b taken along line F-F′ shown in FIG. 7. The main difference between the bipolar junction transistor 1b and the bipolar junction transistor 1 is that the number of collector regions 18 and 20 of the bipolar junction transistor 1b is two. The collector region 18 extends along the horizontal direction D2 and is disposed adjacent to the side 124 of the emitter region 12, and the other collector region 20 extends along the horizontal direction D2 and is disposed adjacent to the side 122 of the emitter region 12. The side 122 is opposite to the side 124. The base regions 14 and 16 and the collector regions 18 and 20 are respectively disposed adjacent to different sides of the emitter region 12, and the base regions 14 and 16 and the collector regions 18 and 20 are not disposed adjacent to the same side of the emitter region 12.

Furthermore, the collector regions 18 and 20 are arranged symmetrically with respect to a center (not labeled) of the emitter region 12. In a top view of the bipolar junction transistor 1b, the collector region 20 may be formed in a strip shape or a rectangular shape. The collector region 20 may include two short sides (i.e., the sides 201 and 203) opposite to each other and two long sides (i.e., the sides 202 and 204) opposite to each other. In FIG. 7, in the horizontal direction D1, there is a shortest distance SD2 between the outer side (i.e., the side 184) of the collector region 18 and the emitter region 12, and there is a shortest distance SD4 between the outer side (i.e., the side 202) of the collector region 20 and the emitter region 12. The shortest distance SD2 is equal to the shortest distance SD4. The cross section of the bipolar junction transistor 1b taken along the horizontal direction D1 is symmetrical, as shown in FIG. 8. The cross section of the bipolar junction transistor 1b taken along the horizontal direction D2 is symmetrical, as shown in FIG. 9. For other details about the bipolar junction transistor 1b, reference may be made to the relevant description of the bipolar junction transistor 1 and are omitted herein.

Compared with the prior art, in the present disclosure, the base region and the collector region are disposed adjacent to different sides of the emitter region. For example, the base region is disposed adjacent to a first side of the emitter region and the collector region is disposed adjacent to a second side of the emitter region, or the base region is disposed adjacent to the first side and the second side of the emitter region and the collector region is disposed adjacent to a third side and a fourth side of the emitter region. It is beneficial to reduce the area of the bipolar junction transistor and improve the electrical performance of the bipolar junction transistor.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A bipolar junction transistor, comprising:
an emitter region;
a base region disposed adjacent to a first side of the emitter region;
a collector region disposed adjacent to a second side of the emitter region; and
an isolation structure disposed between the emitter region and each of the base region and the collector region.

2. The bipolar junction transistor of claim 1, wherein the base region and the collector region are not disposed adjacent to a same side of the emitter region.

3. The bipolar junction transistor of claim 1, wherein the base region is not disposed between the emitter region and the collector region.

4. The bipolar junction transistor of claim 1, wherein in a top view of the bipolar junction transistor, each of the base region and the collector region is formed in a strip shape.

5. The bipolar junction transistor of claim 4, wherein a short side of the collector region is aligned with a long side of the base region.

6. The bipolar junction transistor of claim 1, wherein the base region extends along a first direction, the collector region extends along a second direction, and the first direction is perpendicular to the second direction.

7. The bipolar junction transistor of claim 6, wherein in the second direction, the base region overlaps the emitter region, and the collector region does not overlap each of the emitter region and the base region.

8. The bipolar junction transistor of claim 6, wherein a length of the base region in the first direction and a length of the emitter region in the first direction are the same, and a length of the collector region in the first direction and the length of the emitter region in the first direction are different.

9. The bipolar junction transistor of claim 6, wherein a cross section of the bipolar junction transistor taken along the first direction is asymmetric.

10. The bipolar junction transistor of claim 6, wherein a number of the base regions is two, one of the base regions extends along the first direction and disposed adjacent to the first side of the emitter region, another one of the base regions extends along the first direction and disposed adjacent to a third side of the emitter region, and the third side is opposite to the first side.

11. The bipolar junction transistor of claim 10, wherein in a top view of the bipolar junction transistor, a layout of the emitter region, the base region and the collector region comprises an E shape.

12. The bipolar junction transistor of claim 10, wherein two sides of the collector region opposite to each other in the second direction are respectively aligned with an outer side of each of the base regions.

13. The bipolar junction transistor of claim 6, wherein a number of the collector regions is two, one of the collector regions extends along the second direction and disposed adjacent to the second side of the emitter region, another one of the two collector regions extends along the second direction and disposed adjacent to a fourth side of the emitter region, and the fourth side is opposite to the second side.

14. The bipolar junction transistor of claim 6, wherein the collector region is not disposed adjacent to a fourth side of the emitter region, and the fourth side is opposite to the second side.

15. A bipolar junction transistor, comprising:
an emitter region;
an isolation structure surrounding the emitter region;
a base region disposed adjacent to a first side and a second side of the emitter region; and
a collector region disposed adjacent to a third side and a fourth side of the emitter region.

16. The bipolar junction transistor of claim 15, wherein in a top view of the bipolar junction transistor, the base region is formed in an L shape.

17. The bipolar junction transistor of claim 15, wherein in a top view of the bipolar junction transistor, the collector region is formed in an L shape.

18. The bipolar junction transistor of claim 15, wherein in a top view of the bipolar junction transistor, the base region and the collector region are arranged asymmetrically with respect to a center of the emitter region.

19. The bipolar junction transistor of claim 15, wherein the base region is not disposed between the emitter region and the collector region.

20. The bipolar junction transistor of claim 15, wherein the base region comprises a first portion extending along a first direction and disposed adjacent to the first side of the emitter region and a second portion extending along a second direction and disposed adjacent to the second side of the emitter region, and a length of the first portion in the first direction is different from a length of the second portion in the second direction.
